(19) United States
(12) Patent Application Publication
(10) Pub. No.: US 2013/0280893 A1
(43) Pub. Date: Oct. 24, 2013

(54) METHOD FOR PRODUCTION OF SELECTIVE GROWTH MASKS USING IMPRINT LITHOGRAPHY

(71) Applicant: NANOCRYSTAL ASIA INC., Taipei (TW)

(72) Inventors: Chong-Ming LEE, Taipei (TW); Andrew Eng-Jia Lee, Taipei (TW)

(73) Assignee: Nanocrystal Asia Inc., Taipei (TW)

(21) Appl. No.: 13/867,629

(22) Filed: Apr. 22, 2013

Related U.S. Application Data
(60) Provisional application No. 61/637,019, filed on Apr. 23, 2012.

(51) Int. Cl. H01L 21/027

(52) U.S. Cl. CPC H01L 21/027
USPC 438/479

(57) ABSTRACT

The present invention discloses a method for production of selective growth masks using imprint lithography. The method includes steps of: providing a sapphire substrate, forming a GaN layer, an insulation layer, and a photo-resistive layer, performing imprint lithography, performing exposure and development, performing dry etching, and removing the remained photo-resistive layer. The selective growth masks produced by the method of the present invention make the growth of nanowires cylindrical and perpendicular to the GaN layer, and each nanowire is parallel to one another.

### BACKGROUND OF THE INVENTION

1. Technical Field

The present invention relates to a method for production of selective growth masks. More particularly, the present invention relates to a method for production of selective growth masks using imprint lithography.

2. Description of Related Art

Regarding the technology pertaining to the manufacturing of gallium nitride (GaN) nanowires, the result of the growth of nanowires correlates with the result of the subsequent epitaxy process. If the nanowires thus grown are arcuate or sinusoidal, a flat surface required for the thin-film growth of the subsequent epitaxy process is unlikely to form during the epitaxy lateral overgrowth step, and in consequence the thin-film subsequently grown is likely to crack and be susceptible to lattice dislocation to thereby reduce internal quantum efficiency, reduce the probability of electron-hole recombination, and reduce light output efficiency.

If nanowires grow perpendicularly to the gallium nitride base layer and are parallel to each other, the likelihood that an uneven surface forms during the epitaxy lateral overgrowth step will decrease, thereby increasing internal quantum efficiency.

A conventional nanowires growing process entails forming a selective growth mask which is required for the growth of nanowires. With the selective growth mask being able to control the growth of nanowires, each process produces its unique selective growth mask that brings about its unique type of nanowires. Accordingly, it is imperative to provide a method for production of selective growth masks which precisely control the growth of nanowires, such that the nanowires grow perpendicularly to the gallium nitride base layer and are parallel to each other.

### SUMMARY OF THE INVENTION

The present invention discloses a method for production of selective growth masks using imprint lithography. The method comprises steps of: providing a sapphire substrate, forming a GaN layer, an insulation layer, and a photo-resistive layer, performing imprint lithography, performing exposure and development, performing dry etching, and removing the remained photo-resistive layer. The selective growth masks produced by the method of the present invention make the growth of nanowires cylindrical and perpendicular to the GaN layer, and each nanowire is parallel to one another.

To achieve these and other effects, the present invention provides a method for production of selective growth masks using imprint lithography of the present invention, wherein the method includes steps of: providing a sapphire substrate, wherein the sapphire substrate is a base for forming material layers; forming a GaN layer, an insulation layer, and a photo-resistive layer, wherein the GaN layer is formed on the sapphire substrate, the insulation layer is formed on the GaN layer, and the photo-resistive layer is formed on the insulation layer; performing imprint lithography, wherein the photo-resistive layer is imprinted with a pattern of plural holes so as to transfer the pattern of said holes on the surface of the photo-resistive layer; performing exposure and development, wherein the imprinted photo-resistive layer is illuminated by a light source to form corresponding holes in the photo-resistive layer so as to expose the insulation layer through said holes of the photo-resistive layer; performing dry etching, wherein the insulation layer under said holes of the photo-resistive layer is removed by dry etching and the GaN layer is exposed through said holes of the photo-resistive layer; and removing the remained photo-resistive layer.

By implementing the present invention, at least the following progressive effects can be achieved:

1. The growth of nanowires is accurately controlled by selective growth mask;

2. The nanowires thus formed are perpendicular to the GaN substrate, and are parallel to one another; and

3. A flat surface in epitaxy films by the lateral growth and the coalescence of the nanowires can be formed easily and can improve the efficiency of light emission.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is the flowchart of a method for production of selective growth masks using imprint lithography according to an embodiment of the present invention;

FIG. 2A is a cross-sectional view of a wafer after forming GaN layer on a substrate according to an embodiment of the present invention;

FIG. 2B is a top view of FIG. 2A;

FIG. 3A is a cross-sectional view of a wafer after forming an insulation layer on the GaN layer according to an embodiment of the present invention;

FIG. 3B is a top view of FIG. 3A;

FIG. 4A is a cross-sectional view of a wafer after forming a photo-resistive layer on the insulation layer according to an embodiment of the present invention;

FIG. 4B is a top view of FIG. 4A;

FIG. 5A is a cross-sectional view of a wafer after performing imprint lithography according to an embodiment of the present invention;

FIG. 5B is a top view of FIG. 5A;

FIG. 6A is a cross-sectional view of a wafer after performing exposure and development according to an embodiment of the present invention;

FIG. 6B is a top view of FIG. 6A;

FIG. 7A is a cross-sectional view of a wafer after performing dry etching according to an embodiment of the present invention;

FIG. 7B is a top view of FIG. 7A;

FIG. 8A is a cross-sectional view of a wafer after removing the photo-resistive layer according to an embodiment of the present invention;

FIG. 8B is a top view of FIG. 8A;

FIG. 9A is a cross-sectional view of a wafer after growing of nanowires according to an embodiment of the present invention;

FIG. 9B is a top view of FIG. 9A;

FIG. 10A is a top view of a 4-fold nanowires array according to an embodiment of the present invention;

FIG. 10B is a top view of a 6-fold nanowires array according to an embodiment of the present invention;

FIG. 10C is a macroscopic top view of a 6-fold nanowires array according to an embodiment of the present invention; and

FIG. 10D is a top view of a 12-fold nanowires array according to an embodiment of the present invention.

### DETAILED DESCRIPTION OF THE PREFERRED EMBODIMENTS

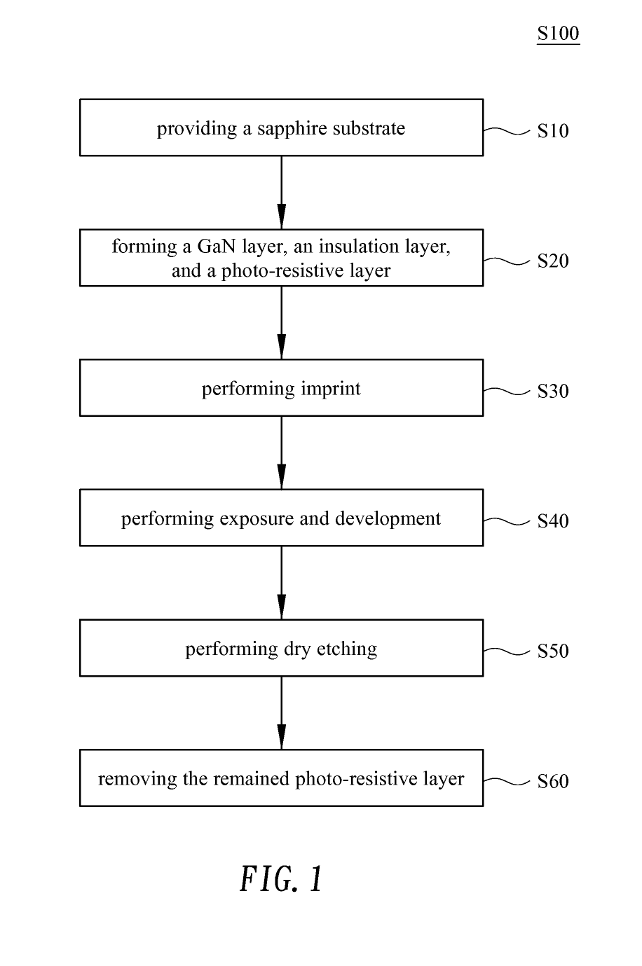

Please refer to FIG. 1 for an embodiment of the present invention, in which a method (S 100) for production of selective growth masks using imprint lithography includes steps of: providing a sapphire substrate (step S10), forming a GaN layer, an insulation layer, and a photo-resistive layer (step S20), performing imprint lithography (step S30), performing exposure and development (step S40), performing dry etching (stepS50), and removing the remained photo-resistive layer (step S60).

The step of providing a sapphire substrate (step S10) shown in FIG. 1 is to provide a substrate as a base for the coming steps of forming material layers. During the process of producing selective growth masks, the substrate can be a silicon (Si) substrate, a silicon carbide (SiC) substrate, a sapphire substrate, or other substrates that can be used in semiconductor wafer production processes, wherein Si substrate can be Si substrate (111) or Si substrate (110). This embodiment is to provide a sapphire substrate 10 as the substrate.

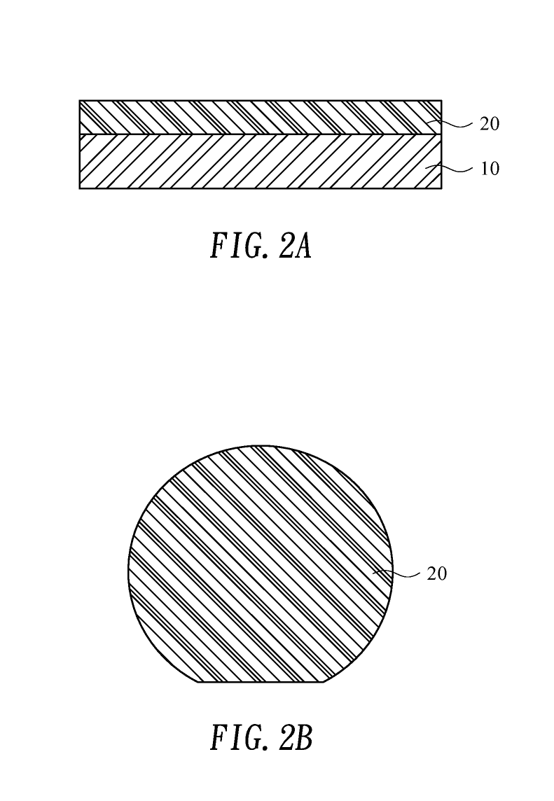

As shown in FIG. 2A and FIG. 2B, the step of forming a GaN layer, an insulation layer, and a photo-resistive layer (step 20) is to firstly form the GaN layer 20 on the sapphire substrate 10 to be the growth base for nanowires. The process of forming the GaN layer 20 on the sapphire substrate 10 can be a Metal-Organic Chemical Vapor Deposition (MOCVD). Generally, the material of the growth base can be III-V or II-VI compound semiconductors, such as GaN, AlN, InN, InGaN, AlGaN, or AlInGaN. This embodiment chooses GaN as the material to form the growth base.

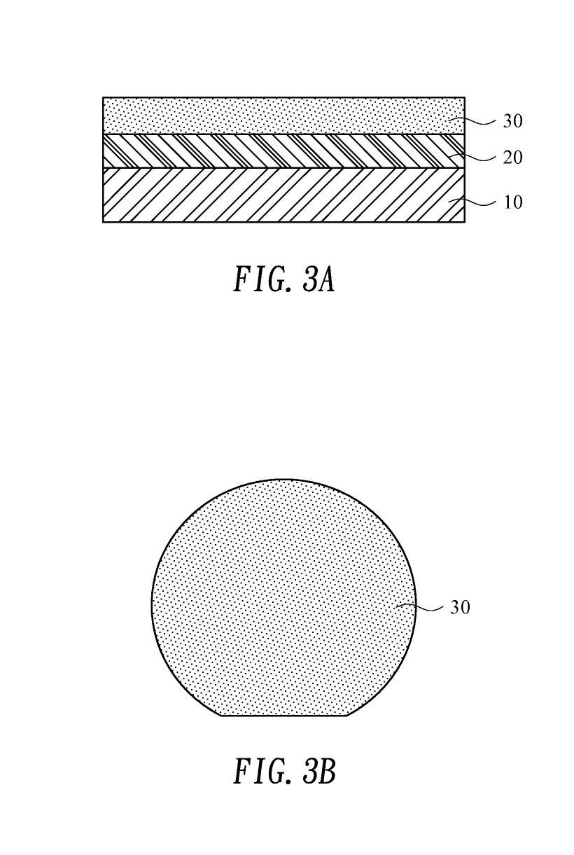

As shown in FIG. 3A and FIG. 3B, the insulation layer 30 is then formed on the GaN layer 20. The forming of the insulation layer 30 is to form a film of insulation material on the GaN layer 20, and can be performed by Plasma Enhanced Chemical Vapor Deposition (PECVD). The implementation of PECVD is to add a radio frequency (RF) voltage between two electrode plates to ionize gas between these electrode plates so as to generate plasma. The generated plasma can help enhancing chemical reactions and help the deposition of the insulation material on the GaN layer 20 so as to form the insulation layer 30. The material of the insulation layer 30 can be silicon oxide (SiO₂) or silicon nitride (SiNₓ).

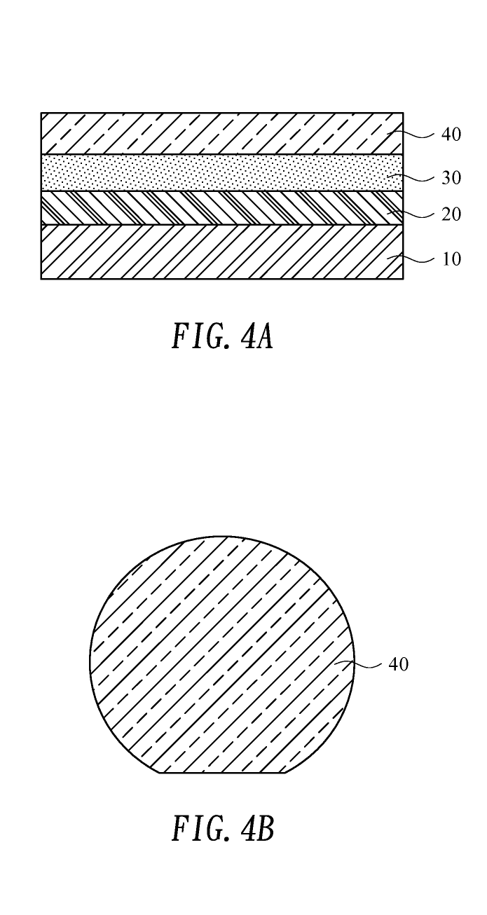

As shown in FIG. 4A and FIG. 4B, the photo-resistive layer 40 is formed by spin-coating a layer of photo-resistive material on the insulation layer 30. The thickness of the photo-resistive layer 40 can be between 20 nm and 2,000 nm, and the thickness of the insulation layer 30 also can be between 20 nm and 2,000 nm. Moreover, the thickness of the photo-resistive layer 40 can be same as the thickness of the insulation layer 30.

The selection of the photo-resistive material used to form the photo-resistive layer 40 is normally depended on a light source used in coming exposure process. When a 248 nm KrF light source is used, the photo-resistive material is usually a polyhydroxystyrene or its derivative; when a 193 nm ArF light source is used, the photo-resistive material is usually an alicyclic epoxy arcylate (ACEA) and its copolymer; when a 13.5 nm EUV light source is used, the photo-resistive material is usually a polyster derivative. In addition to the material mentioned above, photo-resistive material solvent, photoacid agent, cross-linking agent or other agents are also added to enhance the speed of forming the photo-resistive layer 40.

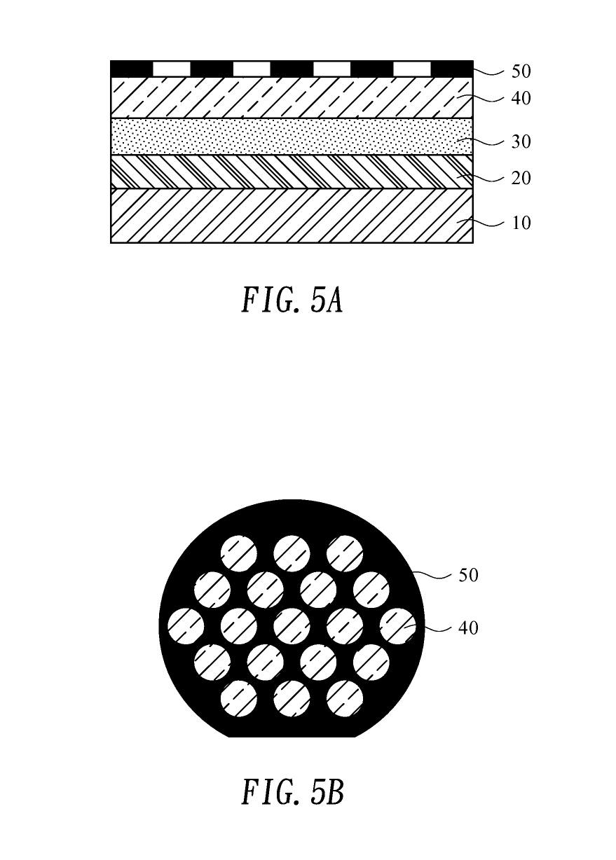

As shown in FIG. 5A and FIG. 5B, the step of performing imprint lithography (step S30) is to imprint the photo-resistive layer 40 to transfer a pattern of multiple holes on the surface of the photo-resistive layer 40. The pattern of the holes is in a lithography mask 50. In other words, the lithography mask 50 has the pattern of the holes. The process of performing imprint is to place the lithography mask 50 on the outer surface of the photo-resistive layer 40, and then to press the lithography mask 50 toward the photo-resistive layer 40 so as to transfer the pattern of the holes on the surface of the photo-resistive layer 40. The dimension of the holes can be modified by different applications. The dimension of the holes can be the size of the holes, the interval of the holes, or the geometry of the holes. The imprint lithography can be nano-meter imprint lithography or micro-meter imprint lithography, according to different application requirements.

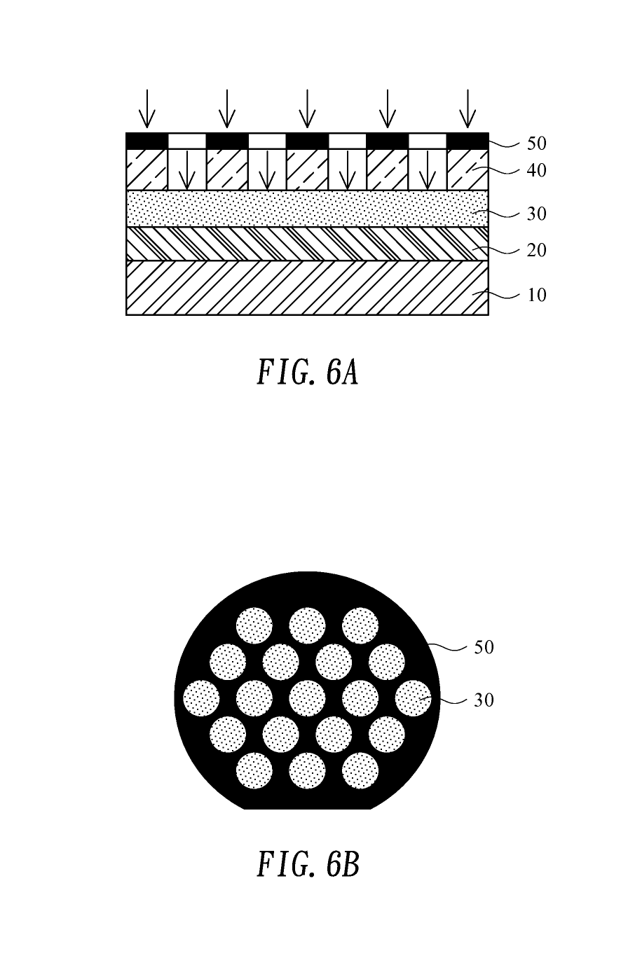

As shown in FIG. 6A and FIG. 6B, the step of performing exposure and development (step S40) is to illuminate the imprinted photo-resistive layer 40 by a light source, wherein the light source is mentioned above. After the process of imprint lithography is performed, the upper surface of the imprinted photo-resistive layer 40 has the pattern of the holes, which is well-distributed. Thus, the light from the light source can transmit through the holes of the lithography mask 50 to expose and dissolve an exposure portion of the photo-resistive layer 40 under the holes of the lithography mask 50.

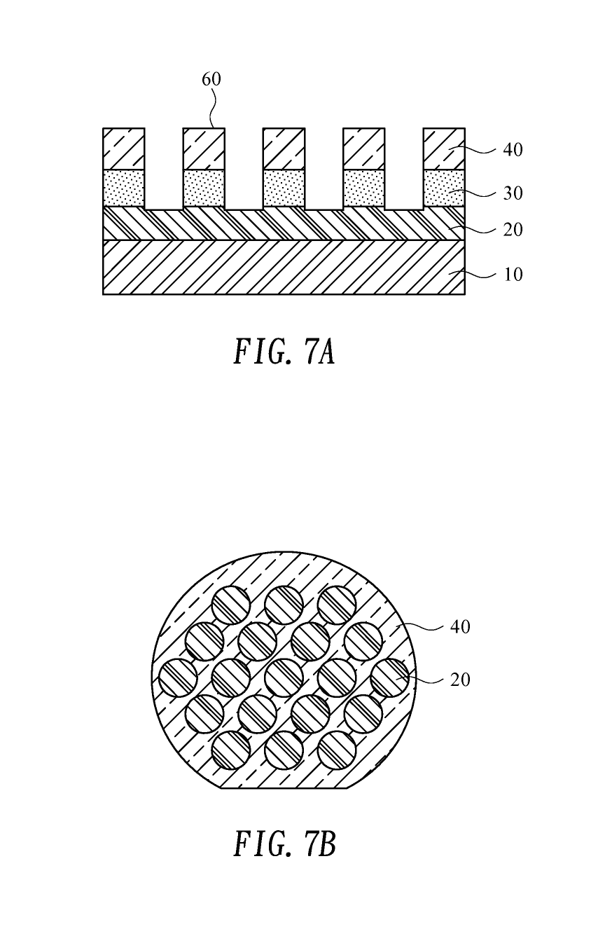

After the exposure portion of the photo-resistive layer 40 is removed and cleaned, a rest portion of the photo-resistive layer 40 under the lithography mask 50 is solidified and the plural corresponding holes of the photo-resistive layer 40 are formed to expose the surface of the insulation layer 30. Thus, after the lithography mask 50 is removed, the photo-resistive layer 40 with plural holes formed on the surface of the insulation layer 30 can act as an etching mask 60 made of the photo-resistive material, as shown in FIG. 7A.

As shown in FIG. 7A and FIG. 7B, the step of performing dry etching (step S50) is to apply etching agent to the insulation layer 30 through the holes of the etching mask 60 so as to remove a part of the insulation layer 30 under the holes until the surface of the GaN layer 20 is exposed. Other part of the insulation layer 30 under the etching mask 60 is not removed due to the protection of the etching mask 60 made of the photo-resistive material, thereby the effect of selective etching is realized.

The step of dry etching (step S50) can be an anisotropic plasma etching that has good directional properties. It is performed by physical bombardment to a surface by plasma ions to generate a chemical reaction and active radical on the surface. There are generally three kinds of dry etching: (1) chemical dry etching, such as sputter etching or ion beam etching; (2) plasma etching; and (3) combined physical-chemical etching, such as reactive ion etching. For example, the reactive ion etching is used in this embodiment.

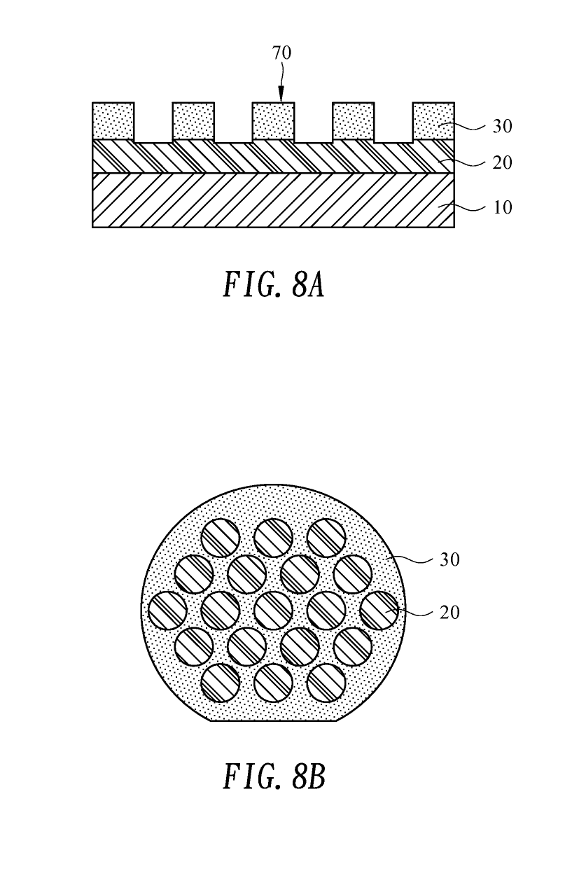

As shown in FIG. 8A and FIG. 8B, the step of removing the remained photo-resistive layer (step S60) is to oxidize the photo-resistive material. Because the photo-resistive material is organic, to oxidize the photo-resistive material can let the organic photo-resistive material become H₂O and CO₂ and be removed effectively. The oxidization can utilize high density O₂ plasma, high density H₂O plasma, or high density UV/O₃ plasma to remove the photo-resistive material, thereby to accelerate the oxidization and to decrease ashy damage. The step of removing the remained photo-resistive layer (step S60) can also be performed by applying spray tools and repetitive soaking of photo-resistive resolving agents to remove the photo-resistive material on the insulation layer 30 and other residue of the photo-resistive material. The photo-resistive resolving agents may include liquid alkali as a main resolving agent and a co-solvent, which helps the photo-resistive material be dissolved easily, in a small amount. The main resolving agent can be NaOH or KOH, and the co-solvent can be isopropanol (IPA), ethylene glycol butyl ether (2-butoxyethanol, BCS), or dipropylene glycol methyl ether (DPM).

After performing of the method (S 100) of the embodiment of the present invention, the sapphire substrate 10 with the GaN layer 20 is covered by the patterned insulation layer 30 that acts as a selective growth mask 70, and the surface of the GaN layer 20 under the holes of the selective growth mask 70 is exposed.

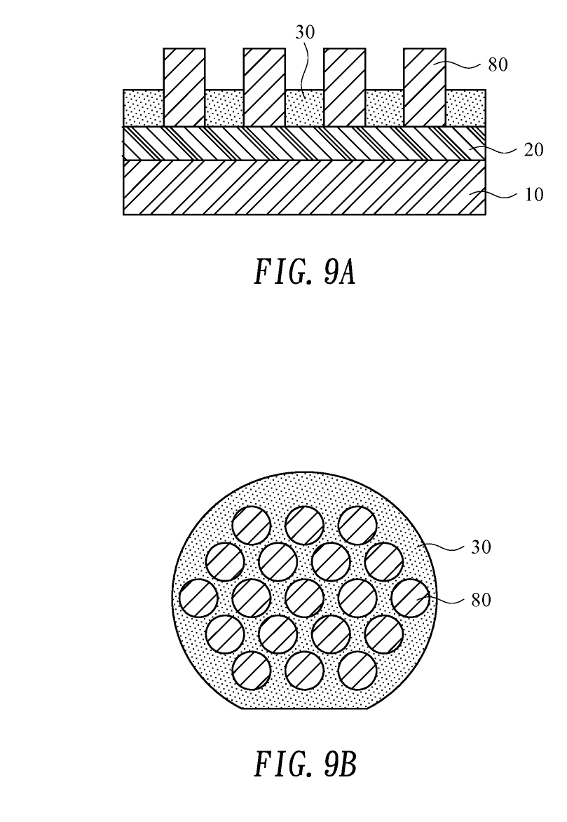

As shown in FIG. 9A and FIG. 9B, the exposed portion of the surface of the GaN layer 20 through the holes of the selective growth mask 70 can then be used to grow nanowires 80 by utilizing selective growth or pulse growth. Because the nanowires 80 cannot grow on the insulation layer 30 that forms the selective growth mask 70, the nanowires 80 can only grow on the surface of the GaN layer 20 through the holes of the selective growth mask 70.

As also shown in FIG. 9A and FIG. 9B, because of the following two reasons: (1) the thickness of the selective growth mask 70 can provide a supporting force generated from the side walls of the holes while the nanowires 80 are growing; and (2) the selective growth mask 70 formed by the insulation layer 30, which is made of silicon, can isolate the lattice defects caused by mismatch of lattice constants between the GaN layer 20 and the sapphire substrate 10 to prevent the lattice defects from affecting the growing nanowires 80. Thus, the nanowires 80 can be very perpendicularly grown, and be parallel to one another.

When the nanowires 80 grow to a predefined length, they start to perform coalescence to one another and generate a low defect semiconductor bulk. When the low defect semiconductor bulk is utilized to manufacture light emitting components, good quantum efficiency can be obtained. Due to different reflective and/or refractive indexes provided by the spacing of the adjacent nanowires 80, the effect of total internal reflection of the light generated by the light emitting components can be eliminated greatly and the scattering angle of the light can be increased, thereby to improve the light emitting efficiency.

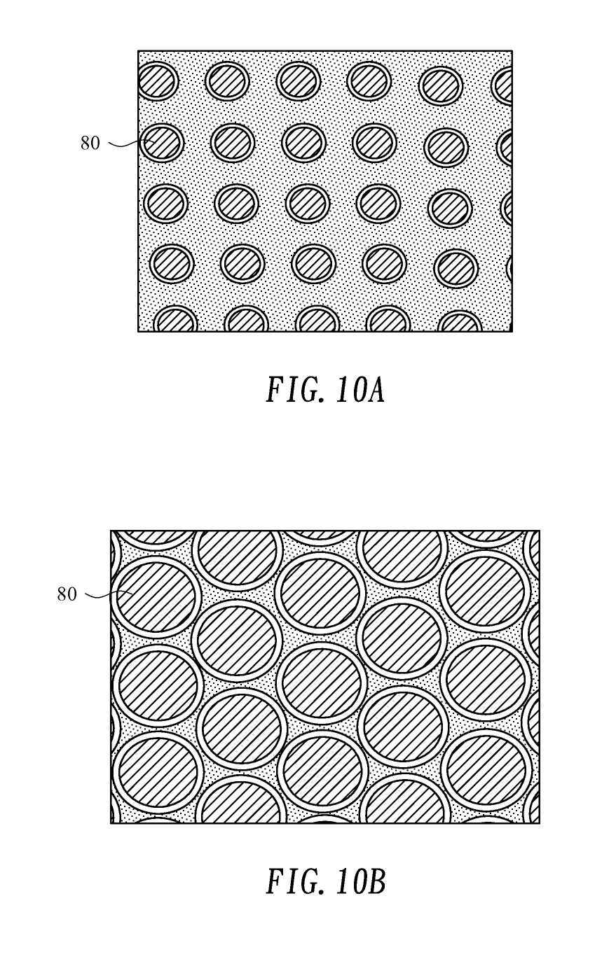

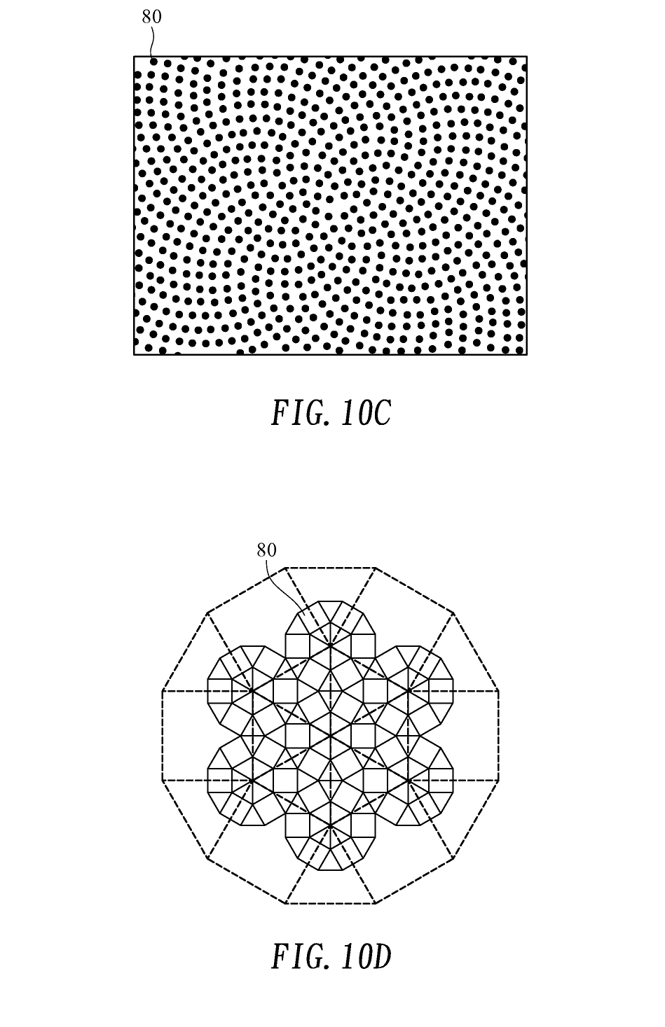

As shown in FIG. 9A and FIG. 10A to FIG. 10D, the nanowires 80 are parallel to one another. The nanowires 80 can be of pillar type or of cone type, and the cross-sectional shape of the nanowires 80 can be of square shape, polygon shape, oval shape, or round shape. The dimensions of the nanowires 80 can be 20˜6,000 nm in length and 20˜2,000 nm in width. The less the width is, the easier the nanowires 80 become cylindrical.

As shown in FIG. 10A to FIG. 10D, the pitch/spacing of the nanowires 80 can be between 20 nm and 2,000 nm, wherein the pitch/spacing of the nanowires 80 is defined as the distance between the center of two adjacent nanowires 80. The nanowire array formed by the nanowires 80 can be hexagonal or quasi-crystal arrangement (such as 4, 6, 12 fold). As for the nanowire symmetry, one direction of the cross-sectional dimension of one of the nanowires 80 can be much less than 1,000 nm, and in an orthogonal direction, the dimension can be substantially equal to 1,000 nm or greater than 1,000 nm. For example, the cross-sectional dimension of a nanowire 80 in the x-axis is equal to 1,000 nm and the cross-sectional dimension of a nanowire 80 in the y-axis is much less than 1,000 nm. Which can be arranged as, the length is 1,000 nm, and the width is far less than 1,000 nm. In one embodiment, a best aspect ratio (length:width) of the nanowires 80 to form a cylinder shape and be mutually parallel is 10:3.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. A method for production of selective growth masks using imprint lithography, comprising steps of:
providing a sapphire substrate, wherein the sapphire substrate is a base for forming material layers;
forming a GaN layer, an insulation layer, and a photo-resistive layer, wherein the GaN layer is formed on the sapphire substrate, the insulation layer is formed on the GaN layer, and the photo-resistive layer is formed on the insulation layer;
performing imprint lithography, wherein the photo-resistive layer is imprinted with a pattern of plural holes so as to transfer the pattern of said holes on the surface of the photo-resistive layer;
performing exposure and development, wherein the imprinted photo-resistive layer is illuminated by a light source to form corresponding holes in the photo-resistive layer so as to expose the insulation layer through said holes of the photo-resistive layer;
performing dry etching, wherein the insulation layer under said holes of the photo-resistive layer is removed by dry etching and the GaN layer is exposed through said holes of the photo-resistive layer; and
removing the remained photo-resistive layer.

2. The method for production of selective growth masks of claim 1, wherein the GaN layer is formed by Metal-Organic Chemical Vapor Deposition (MOCVD).

3. The method for production of selective growth masks of claim 1, wherein the insulation layer is formed by Plasma Enhanced Chemical Vapor Deposition (PECVD).

4. The method for production of selective growth masks of claim 1, wherein the insulation layer is made of silicon oxide (SiO₂) or silicon nitride (SiNₓ).

5. The method for production of selective growth masks of claim 1, wherein the thickness of the insulation layer is 20˜2,000 nm.

6. The method for production of selective growth masks of claim 1, wherein the thickness of the photo-resistive layer is 20˜2,000 nm.

7. The method for production of selective growth masks of claim 1, wherein the thickness of the photo-resistive layer is the same as the thickness of the insulation layer.

8. The method for production of selective growth masks of claim 1, wherein the imprint lithography is a nano-meter imprint lithography or a micro-meter imprint lithography.

9. The method for production of selective growth masks of claim 1, wherein the light source is a 248 nm KrF light source, a 193 nm ArF light source, or a 13.5 nm EUV light source.

10. The method for production of selective growth masks of claim 1, wherein the dry etching is a chemical dry etching, a plasma etching, or a combined physical-chemical etching.
